(19) United States
(12) Patent Application Publication
(10) Pub. No.: US 2025/0234535 A1
(43) Pub. Date: Jul. 17, 2025

(54) VERTICALLY ORIENTED SPLIT GATE NON-VOLATILE MEMORY CELLS, AND METHOD OF MAKING SAME

(71) Applicant: Silicon Storage Technology, Inc., San Jose, CA (US)

(72) Inventors: Yi Song, San Jose, CA (US); JINHO KIM, Saratoga, CA (US); FENG ZHOU, Fremont, CA (US); XIAN LIU, Sunnyvale, CA (US)

(21) Appl. No.: 18/648,291

(22) Filed: Apr. 26, 2024

Related U.S. Application Data
(60) Provisional application No. 63/621,440, filed on Jan. 16, 2024.

(51) Int. Cl. H10B 41/30; H01L 21/28; H01L 29/423; H01L 29/66; H01L 29/788; H10B 41/42

(52) U.S. Cl. CPC H10B 41/30; H10B 41/42; H10D 30/025; H10D 30/0411; H10D 30/689; H10D 30/6892; H10D 64/035

(57) ABSTRACT

A semiconductor device includes a semiconductor substrate having an upper surface with a semiconductor member extending vertically from the upper surface, wherein the semiconductor member has a first conductivity type. A first region of a second conductivity type different than the first conductivity type is formed at a proximal end of the semiconductor member adjacent the upper surface. A second region of the second conductivity type is formed at a distal end of the semiconductor member. A channel region of the semiconductor member extends between the first and second regions. A floating gate laterally wraps around a first portion of the channel region. A control gate laterally wraps around the floating gate. A select gate laterally wraps around a second portion of the channel region. An erase gate laterally wraps around the semiconductor member.

### RELATED APPLICATIONS

This application claims the benefit of U.S. Provisional Application No. 63/621,440, filed Jan. 16, 2024, and which is incorporated herein by reference.

### FIELD OF INVENTION

The present invention relates to non-volatile flash memory cell arrays.

### BACKGROUND OF THE INVENTION

Semiconductor devices with non-volatile memory cells are well known in the art. See for example U.S. Pat. No. 7,868,375, which discloses a four-gate memory cell configuration, and which is incorporated herein by reference for all purposes. Specifically, FIG. 1 of the present application illustrates a pair of split gate memory cells 10 each with spaced apart source and drain regions 14/16 formed in a semiconductor substrate 12. The source region 14 can be referred to as a source line SL (because it commonly is connected to other source regions for other memory cells in the same row or column), and the drain region 16 is commonly connected to a bit line. A channel region 18 of the semiconductor substrate 12 extends between the source/drain regions 14/16. A floating gate 20 is disposed vertically over and insulated from (and directly controls the conductivity of) a first portion of the channel region 18 (and partially vertically over and insulated from the source region 14). Vertical as used herein is the direction generally orthogonal to the general plane of the semiconductor substrate (i.e., generally orthogonal to the plane of the upper surface of the semiconductor substrate before any surface features are formed). A control gate 22 is disposed vertically over and insulated from the floating gate 20. A select gate 24 (also referred to as a word line gate) is disposed vertically over and insulated from (and directly controls the conductivity of) a second portion of the channel region 18, also partially over and insulated from the drain region 16. An erase gate 26 is disposed vertically over and insulated from the source region 14 and is laterally adjacent to the floating gate 20. The erase gate 26 can include a notch that faces an edge of the floating gate 20.

Various combinations of voltages are applied to the control gate 22, select gate 24, erase gate 26 and/or source and drain regions 14/16, to program the split gate memory cell 10 (i.e., inject electrons onto the floating gate 20), to erase the split gate memory cell 10 (i.e., remove electrons from the floating gate 20), and to read the split gate memory cell 10 (i.e., measure or detect the conductivity of the channel region 18, by for example measuring or detecting a read current through the channel region 18, to determine the programming state of the floating gate 20). The split gate memory cell 10 can be erased by placing a high positive voltage on the erase gate 26, and optionally a negative voltage on the control gate 22, to induce tunneling of electrons from the floating gate 20 to the erase gate 26 (leaving the floating gate 20 in a more positively charged state—the erased state). Split gate memory cell can be programmed by placing positive voltages on the control gate 22, erase gate 26, select gate 24 and source region 14, and providing a current to the drain region 16. Electrons will then flow along the channel region 18 from the drain region 16 toward the source region 14, with electrons becoming accelerated and heated whereby some of them are injected onto the floating gate 20 by hot-electron injection (leaving the floating gate 20 in a more negatively charged state—the programmed state). Split gate memory cell 10 can be read by placing positive voltages on the select gate 24 (turning on the portion of channel region 18 under the select gate 24 by making it conductive) and drain region 16 (and optionally on the erase gate 26 and/or the control gate 22), and sensing current flow through the channel region 18. If the floating gate 20 is positively charged (i.e. split gate memory cell 10 is erased), the split gate memory cell 10 will turn on because the both portions of the channel region 18 are conductive due to the lack of electrons on the floating gate 20, and electrical current will flow from drain region 16 to source region 14 (i.e. the split gate memory cell 10 is sensed to be in its erased “1” state based on sensed current flow). If the floating gate 20 is negatively charged (i.e. split gate memory cell 10 is programmed), the portion of channel region 18 under the floating gate is turned off (low conductivity), thereby preventing appreciable current flow (i.e., the split gate memory cell 10 is sensed to be in its programmed “0” state based on no, or minimal, current flow). Memory cells 10 are considered non-volatile because they maintain their program state even when power is not applied to the semiconductor device.

Because the channel region 18 is formed along the planar surface of the semiconductor substrate, as device geometries get smaller, so too does total area (e.g. width) of the channel region. This reduces the current flow between the source and drain regions, requiring, among other things, more sensitive sense amplifiers to detect the state of the memory cell. Because the problem of shrinking the lithography size thereby reducing the channel width affects all semiconductor devices, a Fin-FET type of structure has been proposed. In a Fin-FET type of structure, a fin shaped member of semiconductor material connects the source to the drain regions. The fin shaped member has two parallel side surfaces extending up and terminating in a top surface. Current from the source region to the drain region can then flow along the two side surfaces and the top surface in the horizontal direction (i.e., direction parallel to the general plane of the semiconductor substrate). Thus, the width of the channel region is increased, thereby increasing the current flow. However, the width of the channel region is increased without sacrificing more semiconductor real estate by “folding” the channel region into two side surfaces and the top surface, thereby reducing the “footprint” of the channel region. Non-volatile memory cells using such Fin-FETs have been disclosed, where the floating gate and the select gate wrap around the top surface and two side surfaces of the fin shaped member. Some examples of prior art Fin-FET non-volatile memory structures (although the number and configuration of the gates varies from the above described planar example in FIG. 1) include U.S. Pat. Nos. 7,423,310, 7,410,913, 8,461,640, 9,985,042, and 10,468,428. It has also been proposed to form logic devices on fin shaped members. See for example U.S. Pat. Nos. 9,972,630 and 10,312,247.

While forming memory cells on semiconductor fins has provided some scaling benefits, there is a need to further scale down the size of non-volatile memory cells.

### BRIEF SUMMARY OF THE INVENTION

The aforementioned problems and needs are addressed by a semiconductor device, comprising a semiconductor substrate having an upper surface with a semiconductor member extending vertically from the upper surface, wherein the semiconductor member has a first conductivity type, a first region of a second conductivity type different than the first conductivity type formed at a proximal end of the semiconductor member adjacent the upper surface, a second region of the second conductivity type formed at a distal end of the semiconductor member, wherein a channel region of the semiconductor member extends between the first region and the second region, a floating gate laterally wrapping around and insulated from a first portion of the channel region, a control gate laterally wrapping around and insulated from the floating gate, a select gate laterally wrapping around and insulated from a second portion of the channel region, and an erase gate laterally wrapping around and insulated from the semiconductor member.

A method of forming a semiconductor device, comprising, providing a semiconductor substrate having an upper surface, forming a semiconductor member extending vertically from the upper surface, wherein the semiconductor member has a first conductivity type, forming a first region of a second conductivity type different than the first conductivity type at a proximal end of the semiconductor member adjacent the upper surface, forming a second region of the second conductivity type at a distal end of the semiconductor member, wherein a channel region of the semiconductor member extends between the first region and the second region, forming a floating gate laterally wrapping around and insulated from a first portion of the channel region, forming a control gate laterally wrapping around and insulated from the floating gate, forming a select gate laterally wrapping around and insulated from a second portion of the channel region, and forming an erase gate laterally wrapping around and insulated from the semiconductor member.

Other objects and features of the present disclosure will become apparent by a review of the specification, claims and appended figures.

### BRIEF DESCRIPTION OF THE DRAWINGS

FIG. 1 is a side cross sectional view of a conventional non-volatile memory cell.

FIGS. 2A-2E are side cross sectional views showing the steps in forming semiconductor members extending vertically from the upper surface of the semiconductor substrate.

FIG. 2F is a perspective view of the semiconductor member extending vertically from the upper surface of the semiconductor substrate.

FIGS. 3-9 are side cross sectional views showing the formation of a vertically oriented memory cell on one of the semiconductor members.

FIG. 10 is a side cross sectional view of another example of a vertically oriented memory cell on a semiconductor member.

FIGS. 11A-11B are side views showing the bonding of two wafers.

FIG. 12 is a side view showing horizontally oriented logic devices formed on the same semiconductor substrate as a vertically oriented memory cell.

FIG. 13 is a side view showing vertically oriented logic devices formed on the same semiconductor substrate as a vertically oriented memory cell.

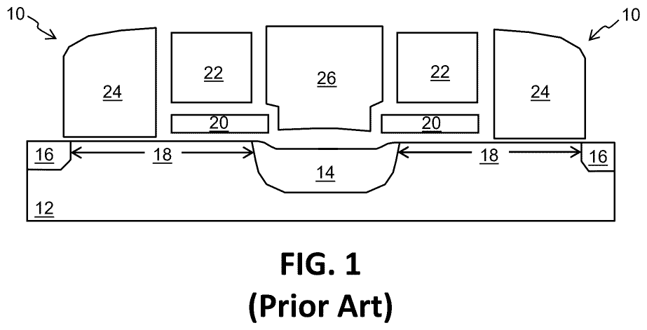

### DETAILED DESCRIPTION OF THE INVENTION

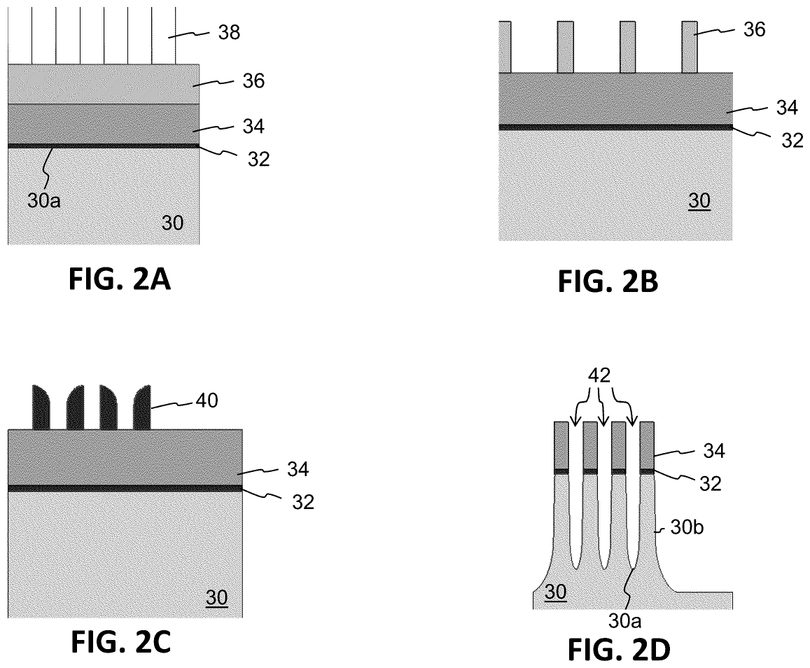

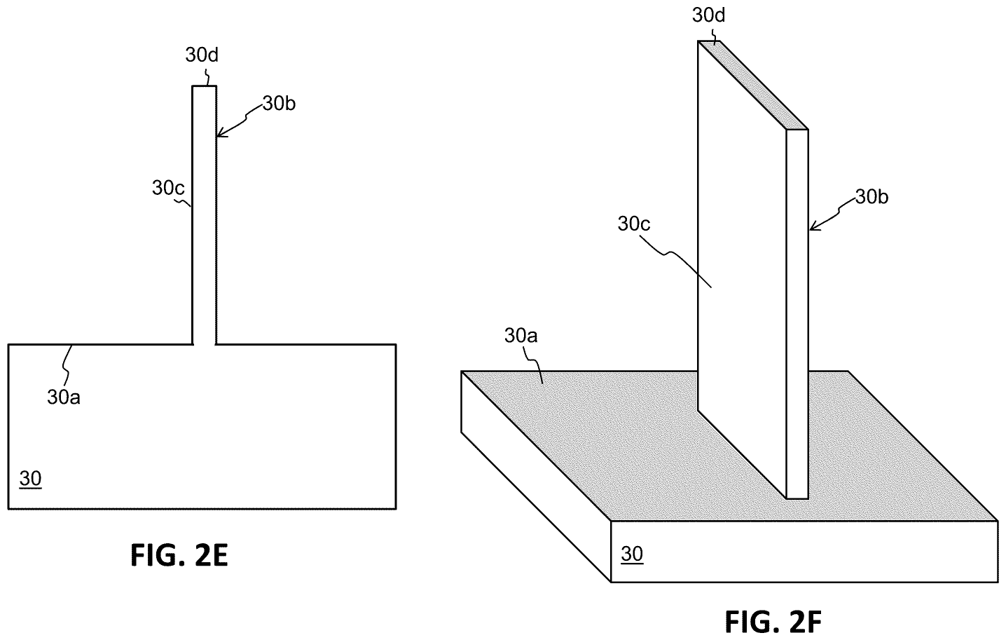

The following disclosure is directed to a semiconductor device containing non-volatile memory cells and to the method of formation of such a semiconductor device. The method of forming the semiconductor device begins by forming semiconductor members extending from the upper surface 30a of a semiconductor (e.g., silicon) substrate 30. Semiconductor member formation may begin by forming an oxide layer 32 (e.g., silicon oxide, silicon dioxide, or both) on the upper surface 30a of a semiconductor substrate 30. A silicon nitride (nitride) layer 34 is formed on oxide layer 32. A mandrel material 36 (i.e., a material having a high etch selectivity relative to the nitride layer 34 underneath, such as SiC) is formed on the nitride layer 34. Photoresist 38 is formed on the mandrel material 36. The photoresist 38 is then patterned, which can include a photolithography process that selectively exposes portions of the photoresist 38, and selectively removes portions of the photoresist 38 to expose selective portions of the underlying material (i.e., the mandrel material 36 in this case). The resulting structure is shown in FIG. 2A.

An etch is performed to remove the exposed portions of mandrel material 36, leaving discrete portions of mandrel material 36 as shown in FIG. 2B (after removal of photoresist 38). Nitride spacers 40 are formed along the sides of the mandrel material 36. Formation of spacers is well known in the art, and involves the deposition of a material over the contour of a structure, followed by an anisotropic etch process, whereby the material is removed from horizontal surfaces of the structure, while the material remains largely intact on vertically oriented surfaces of the structure (typically with a rounded upper surface). Nitride spacers 40 are thus formed by deposition of nitride, followed by anisotropic nitride etch, which leaves nitride spacers 40 on vertical sidewalls of mandrel material 36. An etch is performed to remove mandrel material 36, leaving nitride spacers 40 as shown in FIG. 2C.

One or more etches are performed to remove those portions of nitride layer 34, oxide layer 32 and upper portions of semiconductor substrate 30 that are not underneath nitride spacers 40, which results in the formation of holes or trenches 42 that extend into the semiconductor substrate 30, leaving discrete semiconductor members 30b of the semiconductor substrate 30 extending up from the now recessed upper surface 30a of the semiconductor substrate 30, as illustrated in FIG. 2D. These etches also remove nitride spacers 40. One or more etches may be used to remove nitride layer 34 and oxide layer 32. FIGS. 2E and 2F illustrate one of the semiconductor members 30b, after removal of nitride layer 34 and oxide layer 32, which extends vertically from the semiconductor substrate's upper surface 30a and has a side surface 30c that extends up and terminates in a top surface 30d. While semiconductor member 30b is shown with a rectangular cross section in FIG. 2F, other cross sections can instead be used, including, for example, square, circular, oval or irregularly shaped.

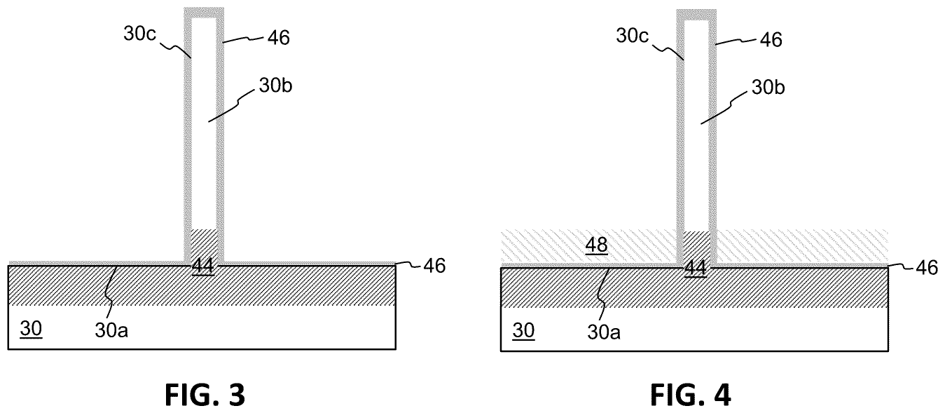

The semiconductor member 30b has a first conductivity type. Implantation may be performed to form a source region 44 in the semiconductor substrate 30 underneath the upper surface 30a and having a second conductivity type different than the first conductivity type. The source region 44 may extend into a lower portion of semiconductor member 30b adjacent the semiconductor substrate upper surface 30a. An insulation layer 46, such as an oxide, is formed on the upper surface 30a of the semiconductor substrate 30, as well as on the semiconductor member's side surface 30c and top surface 30d. The resulting structure is shown in FIG. 3. While this and the following figures show a single semiconductor member 30b, it should be appreciated that a plurality of semiconductor members 30b are formed and processed simultaneously. An insulation material is deposited over the structure, and planarized using a chemical mechanical polish (CMP). A further etch back is performed, leaving insulation layer 48 on the upper surface 30a of the semiconductor substrate 30 and laterally wrapping around a bottom portion of semiconductor member 30b, as shown in FIG. 4.

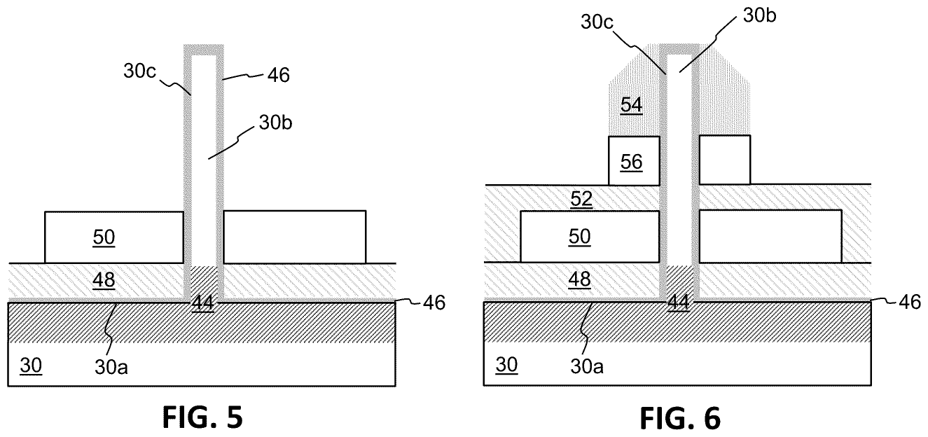

A conductive material is deposited over the structure, and planarized using a chemical mechanical polish (CMP). A further etch back of the insulation layer 48 is performed, leaving a layer of the conductive material on the insulation layer 48. A photolithography process can be used to remove portions of the layer of conductive material, leaving a first block of conductive material 50 that is disposed on insulation layer 48, and laterally wraps around but is insulated from the side surface 30c of semiconductor member 30b, as shown in FIG. 5. An optional insulation layer deposition may be performed at this stage, to thicken the exposed portion of insulation layer 46 on the semiconductor member 30b above first block of conductive material 50 (to increase the insulation thickness between the floating gate (not yet formed) and the semiconductor member 30b).

Insulation material is deposited over the structure and etched back, to form an insulation layer 52 on the first block of conductive material 50. Conductive material is deposited over the structure, planarized using a chemical mechanical polish (CMP), and further etched back, leaving a layer of the conductive material on the insulation layer 52. An insulation material deposition and etch back can be used to form an insulation spacer 54 on the conductive material and laterally wraps around the semiconductor member 30b. An etch can be used to remove the conductive material except for a second block of conductive material 56 under the insulation spacer 54 (i.e., insulation spacer 54 is used to define the second block of conductive material 56), as illustrated in FIG. 6. The second block of conductive material 56 is disposed on insulation layer 52, and laterally wraps around and is insulated from the side surface 30c of semiconductor member 30b.

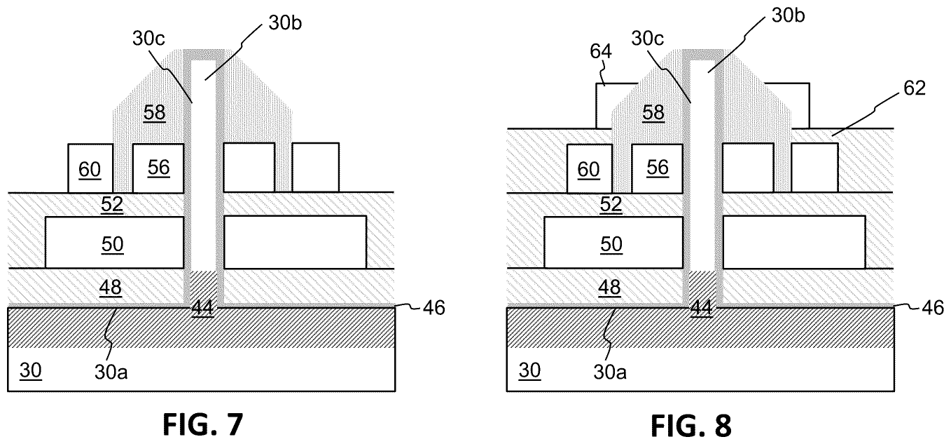

Insulation spacer 54 optionally may be removed (e.g., by an insulation material etch). An insulation material deposition and etch back can be used to form insulation spacer 58 on the second block of conductive material 56 (which may optionally include insulation spacer 54 if not previously removed) and on insulation layer 52 (including along the outer exposed side of the second block of conductive material 56). Conductive material (e.g., doped polysilicon) is deposited over the structure, and planarized using a chemical mechanical polish (CMP). A further etch back is performed, leaving a layer of the conductive material on the insulation layer 52. A photolithography process can be used to remove portions of the layer of conductive material, leaving a third block of conductive material 60, which laterally wraps around and is insulated from the second block of conductive material 56, as shown in FIG. 7.

Insulation material, such as oxide, is deposited over the structure and etched back, to form an insulation layer 62 on and around the third block of conductive material 60. Conductive material is deposited over the structure, and planarized using a chemical mechanical polish (CMP). A further etch back is performed, leaving a layer of the conductive material on the insulation layer 62. A photolithography process can be used to remove portions of the layer of conductive material, leaving a fourth block of conductive material 64, which laterally wraps around insulation spacer 58 and semiconductor member 30b, as shown in FIG. 8.

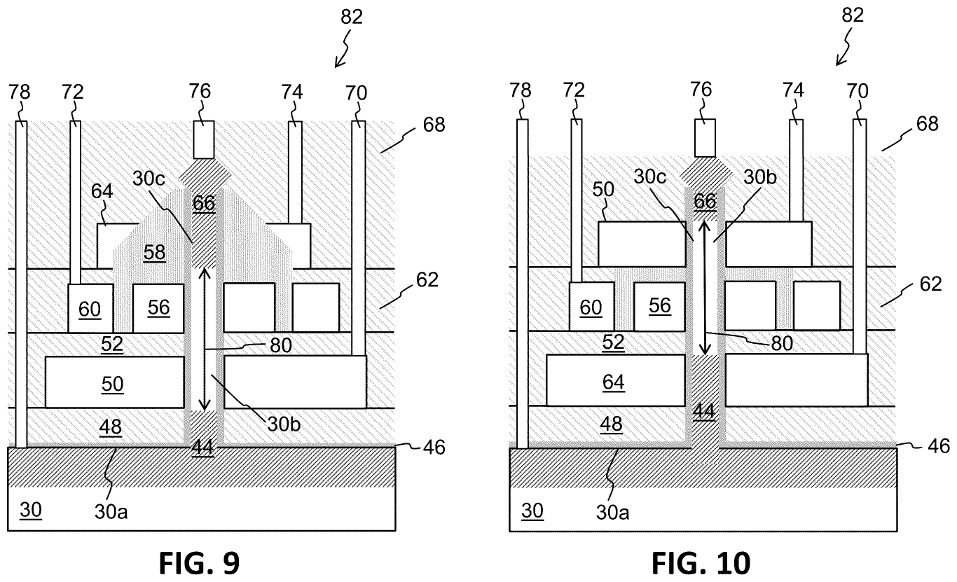

An etch is used to remove the insulation layer 46 on the top surface 30d of the semiconductor member 30b. Epitaxial growth with in-situ doping or implantation, or both, are used to form a drain region 66 at the top surface 30d of semiconductor member 30b, where the drain region 66 has the second conductivity type. Additional insulation material 68 can be deposited. Selective etching can be performed to create contact vias through the various insulation materials, which are then filled with conductive material to form electrical contacts extending through the insulation materials to make contact with the first block of conductive material 50 (electrical contact 70), with the third block of conductive material 60 (electrical contact 72), with the fourth block of conductive material 64 (electrical contact 74), with the drain region 66 (electrical contact 76), and with the source region 44 (electrical contact 78). The resulting structure is shown in FIG. 9.

Each memory cell 82 includes a source region 44 formed at a proximal portion of the semiconductor member 30b (where it meets the upper surface 30a of semiconductor substrate 30), and a drain region 66 at a distal portion of the semiconductor member 30b. Drain regions 66 can be associated with connections to the bit lines, but the electrical connections to the source and drain regions 44/66 for memory cell 82 can be interchangeable (i.e., the direction of current flow during operation can be either direction between source/drain regions 44/66). Therefore, region 44 may be referred to as a first region 44, and region 66 may be referred to as a second region 66. A channel region 80 of the semiconductor member 30b extends between the first region 44 and the second region 66. Contrary to conventional FinFET type memory cells where the channel region extends (and current flowing therethrough runs) in the horizontal direction (i.e., parallel to the general plane of semiconductor substrate upper surface), channel region 80 extends (and the electrical current flowing therethrough runs) in the vertical direction (i.e., orthogonal to the general plane of the semiconductor substrate upper surface 30a). The second block of conductive material 56 is a floating gate that laterally wraps around and is insulated from (and directly controls the conductivity of) a first portion of the channel region 80. The third block of conductive material 60 is a control gate that laterally wraps around and is insulated from the floating gate 56 (for capacitive voltage coupling to the floating gate during operation). The first block of conductive material 50 is a select gate (may also be referred to as a word line gate) that laterally wraps around and is insulated from (and directly controls the conductivity of) a second portion of the channel region 80. The fourth block of conductive material 64 is an erase gate that laterally wraps around the semiconductor member 30b and is sufficiently proximate to, and insulated from, the floating gate 56 for electron tunnelling therebetween during an erase operation. The erase gate 64 can laterally wrap around at least a portion of second region 66.

The above described insulation layers 48, 52, 62, 68 can be made from, for example, oxide (e.g., silicon oxide, silicon dioxide, or a combination of both), silicon nitride, or any other appropriate insulation material known in the art. The above described blocks of conductive materials 50, 56, 60, 64 can be, for example, polysilicon, metal materials, or a combination of both. Metal materials have the advantage of having better conductivity characteristics, where polysilicon can provide better control performance in manufacturing and operation. The theory of operation (program, erase, read) is generally the same as that of the planar split gate non-volatile memory cells described above.

The vertically oriented memory cell 82 has numerous advantages. Forming memory cells 82 on vertically extending semiconductor members 30b allows for more memory cells to be formed in the same square area of the semiconductor substrate's upper surface. Because the gates 50, 56, 60 and 64 laterally wrap around the channel region 80, and control gate 60 wraps around floating gate 56, they can be made smaller without sacrificing performance, thus allowing further scaling down of the size of each memory cell 82. The vertical orientation of the memory cell 82 can provide superior program disturb performance (i.e., programming a memory cell runs less of a risk of adversely affecting the programming state of neighboring memory cells compared to horizontally oriented memory cells). While acceptable performance can be achieved by having the memory cell gates 50, 56, 60, 64 laterally wrap around the semiconductor member 30b in a manner that is not complete (i.e., partially lateral wraps such that each gate has an open ring shape when viewed from above), superior performance can be achieved by having the select gate 50, floating gate 56, control gate 60 and erase gate 64 completely laterally wrap around the semiconductor member 30b (i.e., each gate has a closed ring shape when viewed from above).

For the memory cell configuration shown in FIG. 9, the select gate 50 is formed vertically over and insulated from the semiconductor substrate upper surface 30a, the floating gate 56 and control gate 60 are formed vertically over and insulated from the select gate 50, and the erase gate 64 is formed vertically over and insulated from the floating gate 56 and control gate 60. However, the locations of the select gate 50 and erase gate 64 can be reversed, as shown in FIG. 10. Specifically, erase gate 64 can be formed vertically over and insulated from the semiconductor substrate upper surface 30a by insulation layers 46, 48 (and laterally wrap around at least a portion of first region 44), the floating gate 56 and control gate 60 can be formed vertically over and insulated from the erase gate 64, and the select gate 50 can be formed vertically over and insulated from the floating gate 56 and control gate 60.

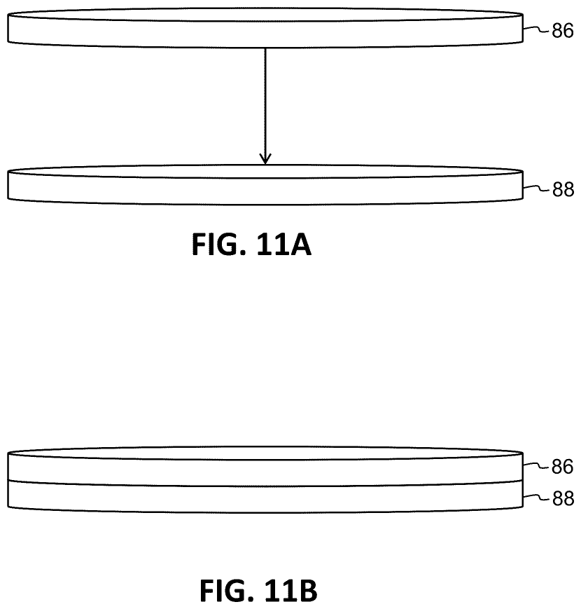

The vertically oriented memory cells 82 can be readily combined with conventional low and high voltage transistors. Conventional transistors can include horizontally oriented planar or FinFET transistors. Low and high voltage transistors have a single gate controlling the conductivity of a channel region, where thicker insulation between the gate and channel region is used for the high voltage transistors since they are operated at higher voltages relative to the lower voltage transistors. For example, wafer bonding can be used to bond a first wafer 86 containing the vertically oriented memory cells 82 to a second wafer 88 containing conventional low and high voltage transistors, as shown in FIGS. 11A and 11B.

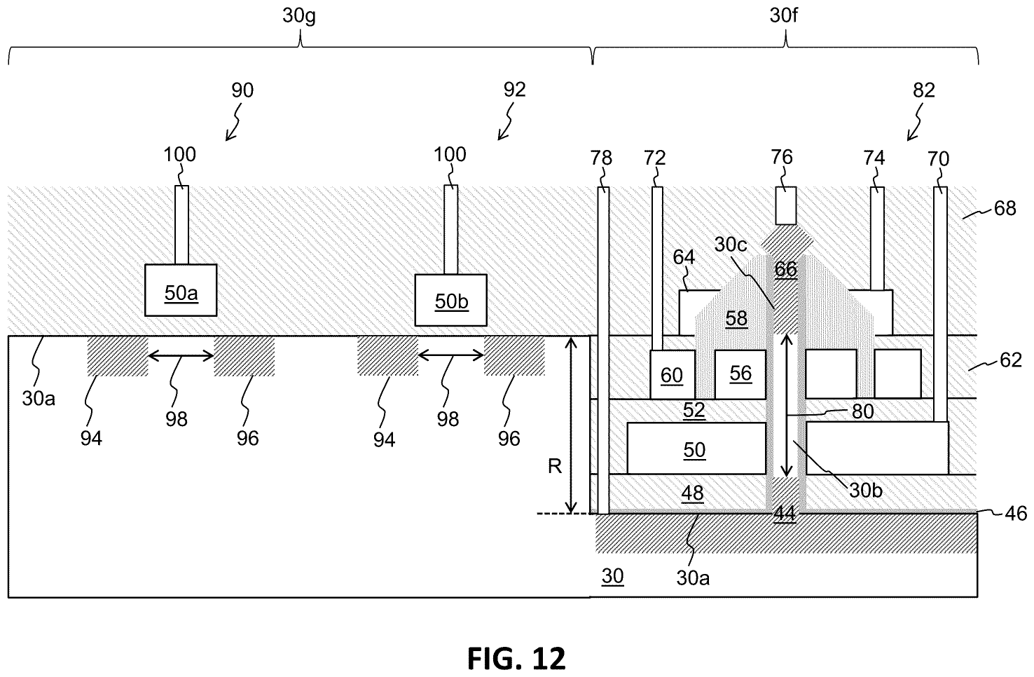

As another example, the semiconductor substrate can comprise a memory area 30f and a logic area 30g. The upper surface 30a of the semiconductor substrate 30 on which the memory cells 82 are formed in the memory area 30f can be recessed by a recess amount R relative to the upper surface 30a of the semiconductor substrate in the logic area 30g of the semiconductor substrate on which high voltage transistors 90 and low voltage transistors 92 are formed (to accommodate the higher profile of vertically oriented memory cells 82 relative to horizontally oriented transistors 90, 92), as illustrated in FIG. 12. The same conductive layer used to form the select gate 50 in memory cell 82 can be used to form a transistor gate 50a for high voltage transistor 90, and a transistor gate 50b for low voltage transistor 92. Transistors 90/92 both include a transistor source region 94, a transistor drain region 96, and a horizontally oriented transistor channel region 98 extending therebetween parallel to the upper surface 30a of the semiconductor substrate 30. Transistor gate 50a extends over (and controls the conductivity of) transistor channel region 98 of the high voltage transistor 90, and transistor gate 50b extends over (and controls the conductivity of) transistor channel region 98 of the low voltage transistor 92. The thickness of the insulation between the transistor gate 50a and the upper surface 30a of semiconductor substrate 30 can be greater than that for transistor gate 50b (to accommodate higher operating voltages). Transistor contacts 100 can be formed to make electrical contact with the transistor high/low voltage gates 50a, 50b. This example has a first transistor (i.e., low voltage transistor 92) and a second transistor (i.e., high voltage transistor 90) formed on the same planar surface 30a of substrate 30 in the logic area 30g.

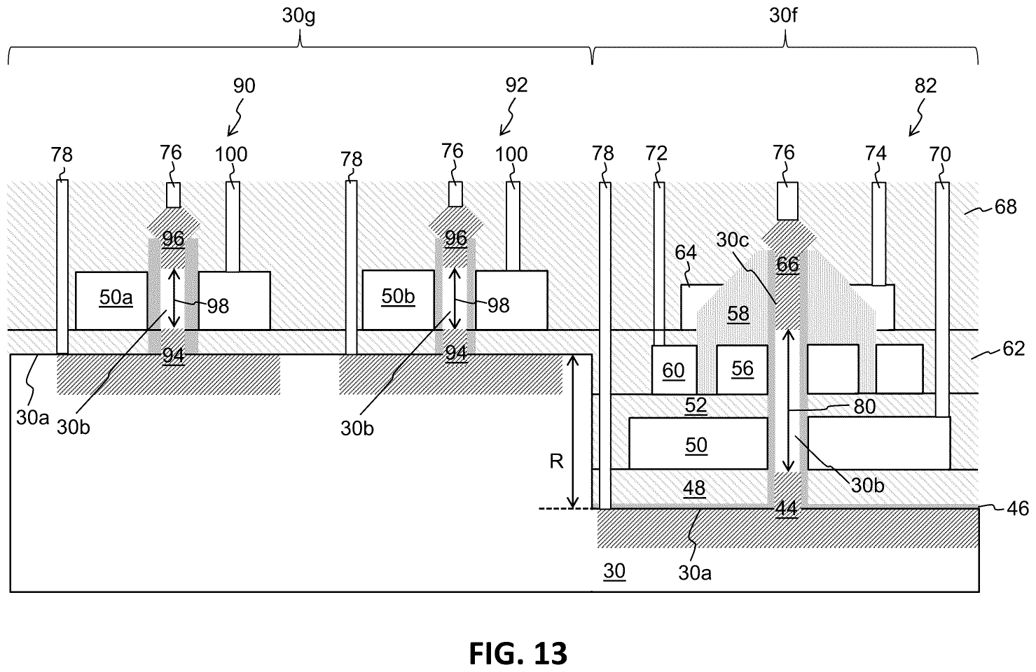

FIG. 13 illustrates another example, where vertically extending semiconductor members 30b are also formed in the logic area 30g of the semiconductor substrate 30, the high and low voltage gates 50a/50b laterally wrap around the respective semiconductor members 30b (with insulation between the high voltage gate 50a and the semiconductor member 30b that is thicker than that for low voltage gate 50b), the transistor source region 94 is formed at a proximal end of the semiconductor member 30b, the transistor drain region 96 is formed at the distal end of the semiconductor member 30b, and the transistor channel region 98 extends vertically through the semiconductor member 30b between the transistor source/drain regions 94, 96. This example has a first transistor (i.e., low voltage transistor 92) and a second transistor (i.e., high voltage transistor 90) formed on vertically extending second and third semiconductor members 30b respectively in the logic area 30g.

It is to be understood that the above is not limited to the examples(s) described above and illustrated herein but encompasses any and all variations falling within the scope of any claims. For example, the memory cell configuration in FIG. 12 (which is the same as that shown in FIG. 9) could instead be the memory cell configuration of FIG. 10. Similarly, the memory cell configuration in FIG. 13 (which is the same as that shown in FIG. 9) could instead be the memory cell configuration of FIG. 10. Those skilled in the art understand that the transistor source and drain regions are interchangeable; therefore, as used herein, transistor source and drain regions merely refer to regions of conductivity type different than that of the intervening channel region, and are interchangeable. Any references to the examples or invention herein are not intended to limit the scope of any claim or claim term, but instead merely relate to one or more features that may be covered by one or more of the claims. Materials, processes and numerical examples described above are examples only, and should not be deemed to limit the claims.

What is claimed is:

1. A semiconductor device, comprising:
a semiconductor substrate having an upper surface with a semiconductor member extending vertically from the upper surface, wherein the semiconductor member has a first conductivity type;
a first region of a second conductivity type different than the first conductivity type formed at a proximal end of the semiconductor member adjacent the upper surface;
a second region of the second conductivity type formed at a distal end of the semiconductor member, wherein a channel region of the semiconductor member extends between the first region and the second region;
a floating gate laterally wrapping around and insulated from a first portion of the channel region;
a control gate laterally wrapping around and insulated from the floating gate;
a select gate laterally wrapping around and insulated from a second portion of the channel region; and
an erase gate laterally wrapping around and insulated from the semiconductor member.

2. The semiconductor device of claim 1, wherein:
the floating gate completely laterally wraps around the first portion of the channel region;
the control gate completely laterally wraps around the floating gate;
the select gate completely laterally wraps around the second portion of the channel region; and
the erase gate completely laterally wraps around the semiconductor member.

3. The semiconductor device of claim 1, wherein:
the floating gate and the control gate are disposed vertically over the select gate; and
the erase gate is disposed vertically over the floating gate and the control gate.

4. The semiconductor device of claim 3, wherein the erase gate laterally wraps around at least a portion of the second region of the second conductivity type.

5. The semiconductor device of claim 1, wherein:
the floating gate and the control gate are disposed vertically over the erase gate; and
the select gate is disposed vertically over the floating gate and the control gate.

6. The semiconductor device of claim 5, wherein the erase gate laterally wraps around at least a portion of the first region of the second conductivity type.

7. The semiconductor device of claim 1, comprising:
a first transistor source region and a first transistor drain region of the second conductivity type formed in the semiconductor substrate adjacent the upper surface, wherein a first transistor channel region extends parallel to the upper surface between the first transistor source region and the first transistor drain region; and
a first transistor gate disposed over and insulated from the first transistor channel region by insulation material having a first thickness.

8. The semiconductor device of claim 7, wherein:
the semiconductor substrate comprises a memory area and a logic area;
the upper surface of the semiconductor substrate in the memory area is recessed relative to the upper surface of the semiconductor substrate in the logic area;
the semiconductor member, the first region, the second region, the channel region, the floating gate, the control gate, the select gate, and the erase gate are disposed in the memory area; and
the first transistor source region, the first transistor drain region, the first transistor channel region and the first transistor gate are disposed in the logic area.

9. The semiconductor device of claim 8, comprising:
a second transistor source region and a second transistor drain region of the second conductivity type formed in the semiconductor substrate adjacent the upper surface, wherein a second transistor channel region extends parallel to the upper surface between the second transistor source region and the second transistor drain region;
a second transistor gate disposed over and insulated from the second transistor channel region by second insulation material having a second thickness greater than the first thickness; and
the second transistor source region, the second transistor drain region, the second transistor channel region and the second transistor gate are disposed in the logic area.

10. The semiconductor device of claim 1, comprising:
a second semiconductor member extending vertically from the upper surface;
a first transistor source region of the second conductivity type formed at a proximal end of the second semiconductor member adjacent the upper surface;
a first transistor drain region of the second conductivity type formed at a distal end of the second semiconductor member, wherein a first transistor channel region of the semiconductor member extends between the first transistor source region and the first transistor drain region; and
a first transistor gate laterally wrapping around and insulated from the first transistor channel region by insulation material having a first thickness.

11. The semiconductor device of claim 10, wherein:
the semiconductor substrate comprises a memory area and a logic area;
the upper surface of the semiconductor substrate in the memory area is recessed relative to the upper surface of the semiconductor substrate in the logic area;
the semiconductor member, the first region, the second region, the channel region, the floating gate, the control gate, the select gate, and the erase gate are disposed in the memory area; and
the second semiconductor member, the first transistor source region, the first transistor drain region, the first transistor channel region and the first transistor gate are disposed in the logic area.

12. The semiconductor device of claim 11, comprising:
a third semiconductor member extending vertically from the upper surface;
a second transistor source region of the second conductivity type formed at a proximal end of the third semiconductor member adjacent the upper surface;
a second transistor drain region of the second conductivity type formed at a distal end of the third semiconductor member, wherein a second transistor channel region of the second semiconductor member extends between the second transistor source region and the second transistor drain region;
a second transistor gate laterally wrapping around and insulated from the second transistor channel region by insulation material having a second thickness greater than the first thickness; and
the third semiconductor member, the second transistor source region, the second transistor drain region, the second transistor channel region and the second transistor gate are disposed in the logic area.

13. A method of forming a semiconductor device, comprising:
providing a semiconductor substrate having an upper surface;
forming a semiconductor member extending vertically from the upper surface, wherein the semiconductor member has a first conductivity type;
forming a first region of a second conductivity type different than the first conductivity type at a proximal end of the semiconductor member adjacent the upper surface;
forming a second region of the second conductivity type at a distal end of the semiconductor member, wherein a channel region of the semiconductor member extends between the first region and the second region;
forming a floating gate laterally wrapping around and insulated from a first portion of the channel region;
forming a control gate laterally wrapping around and insulated from the floating gate;
forming a select gate laterally wrapping around and insulated from a second portion of the channel region; and
forming an erase gate laterally wrapping around and insulated from the semiconductor member.

14. The method of forming a semiconductor device of claim 13, wherein:
the floating gate completely laterally wraps around the first portion of the channel region;
the control gate completely laterally wraps around the floating gate;
the select gate completely laterally wraps around the second portion of the channel region; and
the erase gate completely laterally wraps around the semiconductor member.

15. The method of forming a semiconductor device of claim 13, wherein:
the floating gate and the control gate are disposed vertically over the select gate; and
the erase gate is disposed vertically over the floating gate and the control gate.

16. The method of forming a semiconductor device of claim 15, wherein the erase gate laterally wraps around at least a portion of the second region of the second conductivity type.

17. The method of forming a semiconductor device of claim 13, wherein:
the floating gate and the control gate are disposed vertically over the erase gate; and
the select gate is disposed vertically over the floating gate and the control gate.

18. The method of forming a semiconductor device of claim 17, wherein the erase gate laterally wraps around at least a portion of the first region of the second conductivity type.

19. The method of forming a semiconductor device of claim 13, comprising:
forming a first transistor source region and a first transistor drain region of the second conductivity type in the semiconductor substrate adjacent the upper surface, wherein a first transistor channel region extends parallel to the upper surface between the first transistor source region and the first transistor drain region; and
forming a first transistor gate disposed over and insulated from the first transistor channel region by insulation material having a first thickness.

20. The method of forming a semiconductor device of claim 19, wherein:
the semiconductor substrate comprises a memory area and a logic area;
the upper surface of the semiconductor substrate in the memory area is recessed relative to the upper surface of the semiconductor substrate in the logic area;
the semiconductor member, the first region, the second region, the channel region, the floating gate, the control gate, the select gate, and the erase gate are disposed in the memory area; and
the first transistor source region, the first transistor drain region, the first transistor channel region and the first transistor gate are disposed in the logic area.

21. The method of forming a semiconductor device of claim 20, comprising:
forming a second transistor source region and a second transistor drain region of the second conductivity type in the semiconductor substrate adjacent the upper surface, wherein a second transistor channel region extends parallel to the upper surface between the second transistor source region and the second transistor drain region;
forming a second transistor gate disposed over and insulated from the second transistor channel region by second insulation material having a second thickness greater than the first thickness; and
the second transistor source region, the second transistor drain region, the second transistor channel region and the second transistor gate are disposed in the logic area.

22. The method of forming a semiconductor device of claim 13, comprising:
forming a second semiconductor member extending vertically from the upper surface;
forming a first transistor source region of the second conductivity type at a proximal end of the second semiconductor member adjacent the upper surface;
forming a first transistor drain region of the second conductivity type at a distal end of the second semiconductor member, wherein a first transistor channel region of the semiconductor member extends between the first transistor source region and the first transistor drain region; and
forming a first transistor gate laterally wrapping around and insulated from the first transistor channel region by insulation material having a first thickness.

23. The method of forming a semiconductor device of claim 22, wherein:
the semiconductor substrate comprises a memory area and a logic area;
the upper surface of the semiconductor substrate in the memory area is recessed relative to the upper surface of the semiconductor substrate in the logic area;
the semiconductor member, the first region, the second region, the channel region, the floating gate, the control gate, the select gate, and the erase gate are disposed in the memory area; and
the second semiconductor member, the first transistor source region, the first transistor drain region, the first transistor channel region and the first transistor gate are disposed in the logic area.

24. The method of forming a semiconductor device of claim 23, comprising:
forming a third semiconductor member extending vertically from the upper surface;
forming a second transistor source region of the second conductivity type at a proximal end of the third semiconductor member adjacent the upper surface;
forming a second transistor drain region of the second conductivity type at a distal end of the third semiconductor member, wherein a second transistor channel region of the second semiconductor member extends between the second transistor source region and the second transistor drain region;
forming a second transistor gate laterally wrapping around and insulated from the second transistor channel region by insulation material having a second thickness greater than the first thickness; and
the third semiconductor member, the second transistor source region, the second transistor drain region, the second transistor channel region and the second transistor gate are disposed in the logic area.
